(19) United States
(12) Patent Application Publication
(10) Pub. No.: US 2009/0242955 A1
(43) Pub. Date: Oct. 1, 2009

(54) Integrated Circuit, Memory Device and Methods of Manufacturing the Same

(75) Inventor: Dominik Olligs, Dresden (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 12/059,469

(22) Filed: Mar. 31, 2008

(51) Int. Cl. H01L 29/788; H01L 21/336; H01L 27/115; H01L 21/8247

(52) U.S. Cl. 257/315; 257/368; 438/257; 438/289; 257/E27.103; 257/E29.3; 257/E21.68; 257/E21.422

(57) ABSTRACT

An integrated circuit includes: a contact structure with a first stack of at least two conductive layers, and a gate electrode with a second stack of conductive layers, the second stack of layers having the same sequence of conductive layers as the first stack.

### BACKGROUND

Semiconductor devices, such as memory devices or integrated circuits, may comprise transistors, wherein doped regions of the transistors may be coupled to contact structures or to conductive lines. The contact structures or conductive lines comprise conductive materials, such as metals or polysilicon. Gate electrodes may also comprise conductive materials.

The contact structures or conductive lines may be aligned with respect to the gate electrodes, which are coupled to or form another conductive line. The contact structures or conductive lines coupled to the doped regions may be insulated from the gate electrodes. Due to the shrinking dimensions of devices, such as transistors, forming contact structures and conductive lines may result in strict alignment requirements.

### SUMMARY

Described herein is an integrated circuit, a memory device and methods for producing the same. The integrated circuit comprises: a contact structure including a first stack of at least two conductive layers, and a transistor comprising: first and second doped regions formed within a semiconductor substrate and a gate electrode including a second stack of conductive layers with the same sequence of the conductive layers as the first stack. The contact structure is coupled to the first or second doped region.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A and 1B illustrate schematic cross-sectional views of embodiments of the described transistor.

FIG. 2 illustrates a schematic cross-sectional view of an embodiment of the described integrated circuit.

FIG. 3A illustrates a perspective view of an embodiment of the described memory device.

FIG. 3B illustrates an equivalent circuit diagram of the memory device shown in FIG. 3A.

FIG. 4A illustrates a plan view of another embodiment of the described memory device.

FIGS. 4B and 4C illustrate cross-sectional views of the memory device shown in FIG. 4A.

FIG. 5 illustrates a flow diagram of an embodiment of the described method.

FIGS. 6A to 6B illustrate cross-sectional views of an embodiment of the described memory device at different processing steps.

FIGS. 7A and 7B illustrate embodiments of a system.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

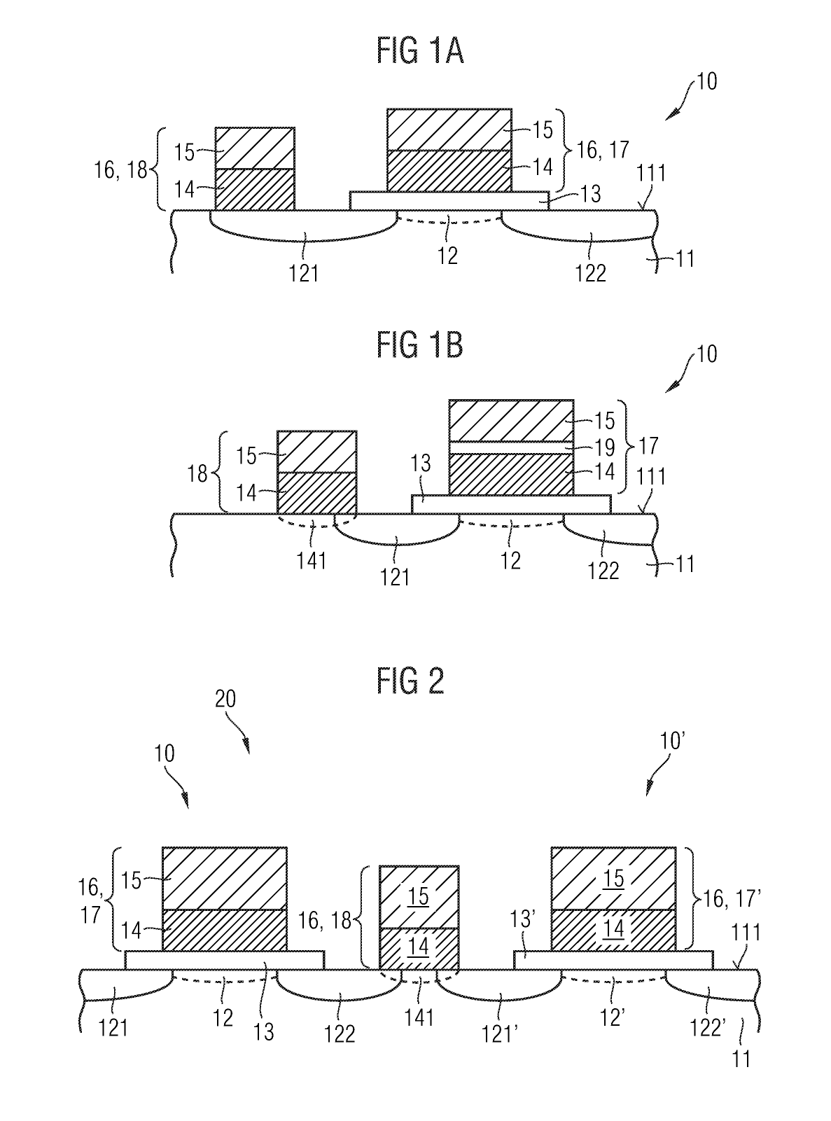

FIG. 1A shows an embodiment of an integrated circuit comprising a transistor 10. The transistor 10 comprises a first and a second doped region 121, 122 formed in a semiconductor substrate or carrier 11. The semiconductor substrate 11 may comprise layers of different materials, such as semiconductor material, metals, insulating materials, organic materials or others, or other devices. The semiconductor substrate 11 may include any semiconductor-based structure that has a semiconductor surface. Substrate and structure are to be understood to include monocrystalline silicon, silicon-on-insulator (SOI), silicon-on-sapphire (SOS), doped and undoped semiconductors, epitaxial layers of silicon supported by a base semiconductor foundation, and other semiconductor structures. The semiconductor need not be silicon-based. The semiconductor may as well be silicon-germanium, germanium, or gallium arsenide.

A channel 12 is formed within the substrate 11 between the first and the second doped region 121, 122. A gate electrode 17 may be formed above a surface 111 of the substrate 11 and adjacent to the channel 12. The gate electrode 17 is configured to control a current flowing through the channel 12 and is insulated from the channel 12 by a gate insulator 13. The gate electrode 17 may comprise a layer stack 16 of at least two conductive layers. A sequence of the layers of the layer stack 16 characterizes the layer stack referring to the materials of the conductive layers. The layer stack 16 may, for instance, comprise a first and a second conductive layer 14, 15. The layer stack 16 may comprise more than two conductive layers, for example three or more. The first conductive layer 14 may be disposed in contact with the gate insulator 13 and the second conductive layer 15 may be disposed on top of the first conductive layer 14.

According to the embodiment shown in FIG. 1A, a contact structure 18 is electrically coupled to one of the doped regions, for example to the first doped region 121. The contact structure 18 and the first doped region 121 are electrically coupled directly, that is they are physically connected with each other. The contact structure 18 may have a low resistivity interface to the first doped region 121. In another embodiment, the contact structure 18 and the first doped region 121 may be coupled indirectly, for instance by a capacity.

The contact structure 18 may be formed completely above the doped region 121, as shown in FIG. 1A, or only partially above the doped region 121. For example, the doped region 121 may be formed by an implantation process after forming the contact structure 18. The doped region 121 may extend on one or on both sides of the contact structure 18 and may extend only partially beneath the contact structure 18 by a diffusion region. In accordance with another embodiment, a contact structure coupled to the second doped region 122 can be formed in the same or in a different manner, for example as a contact structure comprising different conductive layers or as a buried contact structure.

The contact structure 18 comprises a layer stack 16 which comprises conductive layers with the same sequence of the conductive layers as the gate electrode 17. The contact structure 18 comprises a first and a second conductive layer 14, 15. The first and the second conductive layer 14, 15 of the contact structure 18 are made of the same materials and are arranged in the same sequence of layers as the first and the second conductive layer 14, 15 of the gate electrode 17. For example, if the second conductive layer 15 is arranged above the first conductive layer 14 within the layer stack 16 of the gate electrode 17, then the second conductive layer 15 is arranged above the first conductive layer 14 within the layer stack 16 of the contact structure 18 as well. Furthermore, the first and the second conductive layer 14, 15 of the contact structure 18 may have the same thicknesses as the first and the second conductive layers 14, 15 of the gate electrode 17. In accordance with a further embodiment, none of the first or the second conductive layers 14, 15 or only the first conductive layer 14 has the same thickness in the contact structure 18 and the gate electrode 17. The second conductive layer 15 of the contact structure 18 may be thicker than the second conductive layer 15 of the gate electrode 17. The upper surfaces of the second conductive layer 15 of the gate electrode 17 and the contact structure 18 may be arranged at the same height above the substrate surface 111. The upper surface of the second conductive layer 15 is that surface which has the largest distance to the substrate surface 111. According to another embodiment, the contact structure 18 may comprise further layers, for example, an insulating layer or a further conductive layer on top of the second conductive layer 15. According to a further embodiment, the gate electrode 17 may comprise other layers which are non-conductive, such as an insulating layer.

FIG. 1B shows an embodiment of the described integrated circuit comprising such an additional layer. Again a first and a second doped region 121, 122 are formed in a semiconductor substrate 11. A channel 12 is formed within the substrate 11 between the first and the second doped region 121, 122. A gate insulator 13 is disposed in contact with a substrate surface 111 above the channel 12. A gate stack 17 forming a gate electrode is disposed above the gate insulator 13 and may comprise, for instance, a first and a second conductive layer 14, 15, forming a layer stack of conductive layers, and an insulating layer 19 disposed between the first and the second conductive layer 14, 15.

A contact structure 18 that is coupled directly to the first doped region 121 comprises a layer stack which comprises conductive layers in the same sequence of the conductive layers as the gate stack 17. The contact structure 18 comprises a first and a second conductive layer 14, 15. The first and the second conductive layer 14, 15 of the contact structure 18 are made of the same materials, may have the same thicknesses and are arranged in the same sequence of layers as the first and the second conductive layer 14, 15 of the layer stack of the gate stack 17.

The contact structure 18 may be formed only partially above the doped region 121, which it is electrically coupled to, as described with respect to FIG. 1A and shown in FIG. 1B. Accordingly, the doped region 121 may extend only beneath a part of the contact structure 18. Beneath the contact structure 18 a further doped region 141 of the same conductivity type as the doped region 121 may be formed within the substrate 11. The further doped region 141 may improve the electrical connection between the contact structure 18 and the first doped region 121.

The substrate 11 may be a silicon substrate, such as a p-doped or an n-doped single crystalline silicon substrate. The doped regions 121, 122 are doped such that they show the opposite conductivity type with respect to the substrate 11. The gate insulator 13 may comprise silicon oxide, silicon nitride, high-k dielectrics, such as HfO₂, HfSiO (hafniumsilicate), ZrO₂, Al₂O₃, HfAlO, TaO, or any multilayer system comprising any of these materials, such as charge trapping layers. The gate insulator 13 may be formed with a thickness of more than 1 nm, for example 8 nm or more than 8 nm. It may be formed with a thickness of less than 100 nm, for example 50 nm or less than 50 nm. The first conductive layer 14 may comprise a semiconductor material, for example polysilicon having the same conductivity type as the doped regions 121, 122 or a metal. The first layer 14 may be formed with a thickness of more than 10 nm. It may be formed with a thickness of less than 200 nm. The second conductive layer 15 may comprise a semiconductor material, like polysilicon, or a metal, such as tungsten and may be formed with a thickness of more than 10 nm. It may be formed with a thickness of less than 200 nm. In accordance with another embodiment, the first and the second conductive layer 14, 15 may comprise any further suitable conductive material. The insulating layer 19 may comprise a layer stack, which may comprise silicon nitrides, silicon oxides, silicon oxynitrides, high-k dielectrics or other dielectric materials. It may be formed with a thickness of more than 5 nm. It may be formed with a thickness of less than 30 nm.

FIG. 2 shows an embodiment of an integrated circuit. The integrated circuit 20 may comprise a first and a second transistor 10, 10′, wherein the transistors 10, 10′ are partially formed within a semiconductor substrate 11. The first transistor 10 comprises a first and a second doped region 121, 122, a channel 12, a gate insulator 13, and a gate electrode 17. The second transistor 10′ comprises a first and a second doped region 121′, 122′, a channel 12′, a gate insulator 13′, and a gate electrode 17′. The doped regions 121, 121′, 122, 122′, the gate insulators 13, 13′ and the gate electrodes 17, 17′ may be formed as described with respect to FIGS. 1A and 1B. Each gate electrode 17, 17′ comprises a layer stack 16 of conductive layers, and may comprise a first and a second conductive layer 14, 15. The second doped region 122 of the first transistor 10 and the first doped region 121′ of the second transistor 10′ may be electrically coupled to a contact structure 18. The contact structure 18 comprises a layer stack 16 which comprises conductive layers 14, 15 with the same sequence of the conductive layers as the gate electrodes 17, 17′. The first conductive layer 14 of the contact structure 18 is formed in contact with the doped regions 122 and 121′ and may be formed only partially above the doped regions 122, 121′. A further doped region 141 may be formed within the substrate 11 beneath the first conductive layer 14 of the contact structure 18. The further doped region 141 and the doped regions 122, 121′ may have the same conductivity type and may form a continuous doped region.

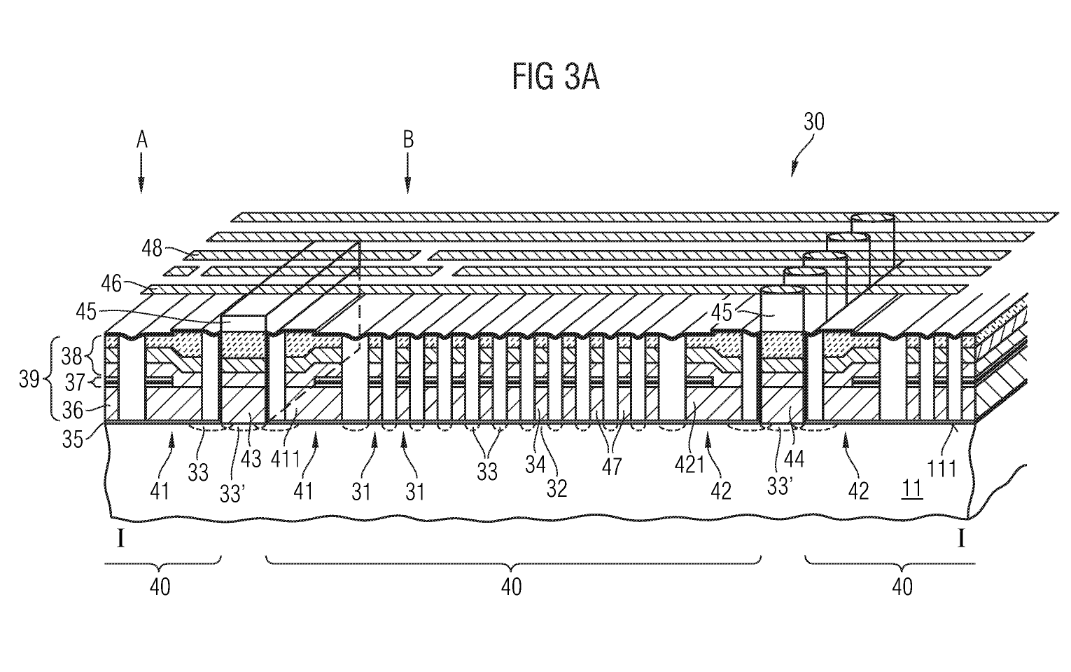

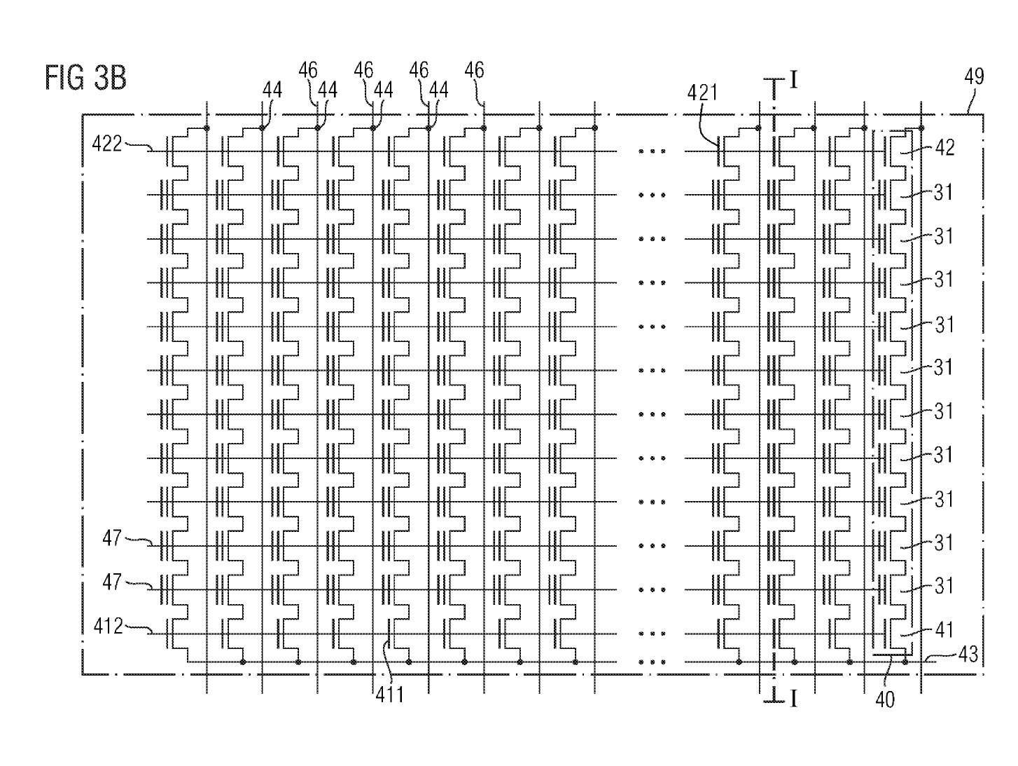

FIG. 3A illustrates schematically a perspective view of an exemplary memory device 30. The memory device 30 comprises a plurality of memory cells 31, which may be implemented as storage transistors 31 in the illustrated embodiment, and a plurality of conductive lines. Each of the storage transistors 31 comprises doped regions 33 formed within a substrate 11. A channel region 32 is formed between each of the doped regions 33. The conductivity of the channel region 32 is controlled via a corresponding gate electrode 34. The gate electrode 34 comprises a gate stack 39. In the illustrated embodiment, the gate stack 39 may comprise a charge storing layer 36 which may be made of a conductive material, such as polysilicon. The charge storing layer 36 is insulated from the substrate 11 by a gate insulator 35. A control gate 38 is provided above the charge storing layer 36. The control gate 38 may comprise a layer stack formed of different conductive materials, such as polysilicon and metals, and is insulated from the charge storing layer 36 by a barrier layer stack 37 which may comprise a silicon oxide layer, followed by a silicon nitride layer, followed by a silicon oxide layer. A plurality of storage transistors 31 are coupled in series, thereby forming a so-called NAND-string 40. A selected NAND-string 40 may be addressed by addressing a common source line 43, activating a corresponding first select transistor 41 and reading the signal via a bit line contact structure 44. The select transistor 41 may be addressed by the first select gate 411. In the embodiment shown in FIG. 3A, the common source line 43 is directly adjacent to a substrate surface 111 and is electrically coupled to a doped region 33 of the first select transistor 41. Accordingly, the source line 43 is in physical contact with the surface 111 of the substrate 11.

In accordance with another embodiment, the source line 43 may be arranged in a metallization plane above the substrate surface 111 and may be coupled to the doped region 33 of the first select transistor 41 via a source line contact structure. The bit line contact structure 44 is electrically coupled to a doped region 33 of a second select transistor 42, and may be in direct contact with the doped region 33 of the second select transistor 42. Adjacent to the source line 43 or the bit line contact structure 44 a doped region 33′ may be formed within the substrate 11. The doped regions 33, 33′ may form a continuous doped region within the substrate 11.

The source line 43 (or a source line contact structure) and/or the bit lines contact structure 44 may comprise a layer stack which comprises conductive layers with the same sequence of the conductive layers as the gate stack 39 of the storage transistors 31. Accordingly, the source line 43 and/or the bit line contact structure 44 may comprise the charge storing layer 36 and the layer stack of the control gate 38 in the same layer sequence as the gate stack 39. The layer stack forming the source line 43 and/or the bit line contact structure 44 may comprise three or more conductive layers, for example the charge storing layer 36 and the three conductive layers of the control gate 38. The source line 43 and/or the bit line contact structure 44 may further comprise an additional conductive material 45 filling up the space between a surface of the gate stack 39 and a metallization plane arranged above the source line 43 or the bit line contact structure 44. The source line 43 and/or the bit line contact structure 44 may be formed self-aligned with respect to the gate stacks 39 of the storing transistors 31.

The common source line 43 may be coupled via a source line contact structure (not shown in FIG. 3A) to further metallization layers. A signal is transmitted via a bit line contact structure 44 to a corresponding bit line 46 which may be disposed in a first metallization layer. The first metallization layer may comprise further interconnection lines 48. In the conductive layer comprising the source line 43, further contact plugs, for example the bit line contacts structures 44 may be formed. Accordingly, the bottom side of the bit line contact structure 44 is disposed at the same height as the bottom side of the common source line 43.

Gate electrodes 34 of the storage transistors 31, which are arranged in a row perpendicular to the cross-sectional plane of FIG. 3A, may be connected to each other, thereby forming word lines 47.

FIG. 3B shows an exemplary equivalent circuit diagram of a memory device comprising NAND-strings 40 such as those which are shown in FIG. 3A, for example. A plurality of NAND-strings 40 form a block 49. Each NAND-string 40 comprises a first select transistor 41, a plurality of storing transistors 31, and a second select transistor 42. A plurality of bit lines 46 and a plurality of word lines 47 are formed so as to perpendicularly intersect each other. The NAND-strings 40 may be formed so as to extend parallel with respect to the direction of the bit lines 46. The common source line 43 is coupled to the source portions of each of the first select transistors 41. The first select transistors 41 are controlled by a first select gate line 412. The first select gate line 412 is coupled to the first select gates 411 of the first select transistors 41, respectively. Furthermore, the drain portions of each of the second select transistors 42 are coupled to a corresponding bit line 46 via a bit line contact structure 44. The second select transistors 42 are controlled by a second select gate line 422. The second select gate line 422 is coupled to the second select gates 421 of the second select transistors 42, respectively.

Although an electrical coupling of the storage transistors forming a NAND architecture is shown in FIGS. 3A and 3B, the storage transistors of the memory device may be coupled in another way, forming, for instance a NOR architecture. The contact structures coupling the doped regions or the conductive lines to a metallization layer may comprise a layer stack which comprises conductive layers in the same sequence as the gate electrodes of the storage transistors.

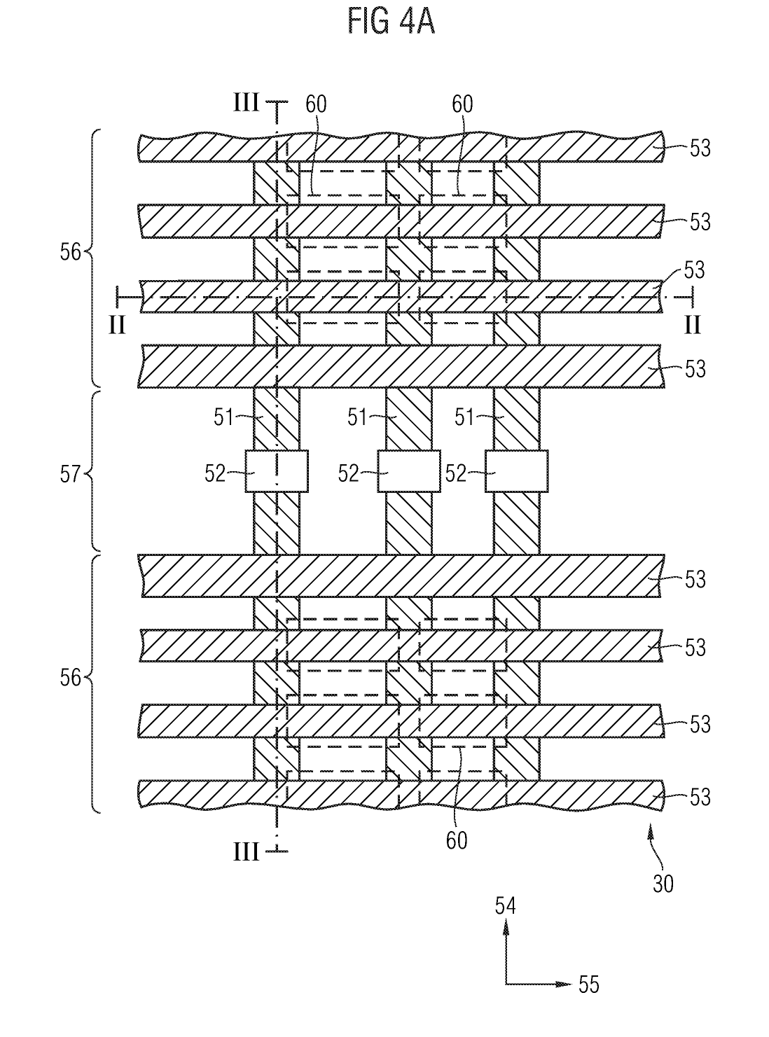

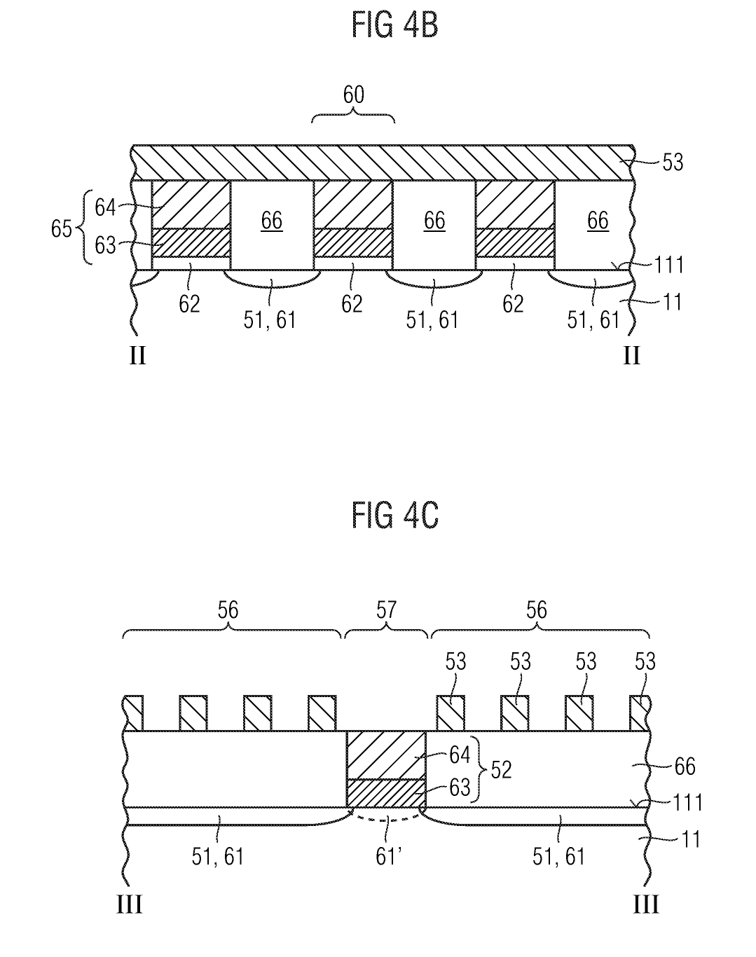

FIGS. 4A to 4C illustrate a memory device with NROM memory cells. FIG. 4A shows a plan view on such a memory device 30. First conductive lines 51 run along a first direction 54 and second conductive lines 53 run along a second direction 55 which intersects the first direction. Memory cells 60 are arranged beneath second conductive lines 53 in between two neighboring first conductive lines 51. Second conductive lines 53, which are word lines, may be arranged in subsets within a first section 56 of the memory device 30. In a second section 57 of the memory device 30, contact structures 52 of first conductive lines (e.g., buried conductive lines) 51 to a higher wiring or metallization plane may be arranged.

FIG. 4B shows a cross sectional view through the memory device 30 along line II-II shown in FIG. 4A, that is, along a second conductive line 53. First conductive lines 51 may be formed within a substrate 11 (e.g., buried conductive lines), such as a semiconductor substrate, and form source/drain regions 61 of memory cells 60. Each memory cell 60 comprises a source and a drain region 61, a charge storing layer 62 and a gate electrode 65 coupled to a second conductive line 53. An insulating material 66 insulates individual memory cells 60 from each other and insulates first lines 51 and second lines 53 from each other. The gate electrodes 65 may comprise a layer stack comprising a first conductive layer 63 and a second conductive layer 64. The first conductive layer 63 is in contact with the charge storing layer 62 and the second conductive layer 64 is disposed on top of the first conductive layer 63. The first conductive layer 63 may comprise, for example, a semiconductor material (e.g., polysilicon) having the same conductivity type as the source/drain regions 61. The charge storing layer 62 may be a layer stack, which may comprise a lower boundary layer, a charge storage layer, and an upper boundary layer. The lower boundary layer is adjacent to a surface 111 of the substrate 11 and the upper boundary layer is adjacent to the gate electrode 65. Information is stored by storing a charge within the charge storage layer, wherein the charge is brought in and removed from the charge storage layer by tunneling of charge carriers through the lower boundary layer. The stored charge determines the threshold voltage of the transistor and can be detected by applying corresponding voltages to the source and drain regions 61 and to the gate electrode 65, respectively.

FIG. 4C shows a cross sectional view through the memory device 30 along line III-III, shown in FIG. 4A, that is along a first conductive line (e.g., buried conductive line) 51. The doped regions 61 are formed within the substrate 11 within the first sections 56. The doped regions 61 form a source or a drain region of adjacent memory cells 60 and a buried bit line 51. In accordance with a further embodiment, the doped regions 61 may be formed in the second section 57, thereby forming a continuous doped region 61 within the substrate 11. Within the first sections 56, the insulating layer 66 is disposed between the substrate surface 111 and the word lines 53. Within the second section 57, a contact structure 52 to the buried bit line 51 is formed. The contact structure 52 is coupled to the doped regions 61 and comprises a layer stack which comprises conductive layers with the same sequence of the conductive layers as the gate electrodes 65. Accordingly, the contact structure 52 may comprise the first and the second conductive layers 63, 64 in the same layer sequence, the same layer thicknesses and material compositions as the gate electrodes 65. Beneath the contact structure 52 a doped region 61′ may be formed within the substrate 11. The doped region 61′ and the doped regions 61 may form a continuous doped region within the substrate 11.

In addition to a floating gate device and a NROM device, the described memory device may be any other memory device comprising at least one transistor, for example, nonvolatile memory devices like charge trapping devices, such as SONOS, TANOS or SANOS devices, in different architectures, such as NAND or NOR architecture. Furthermore, other embodiments may refer to DRAM, MRAM, PCRAM or CBRAM devices.

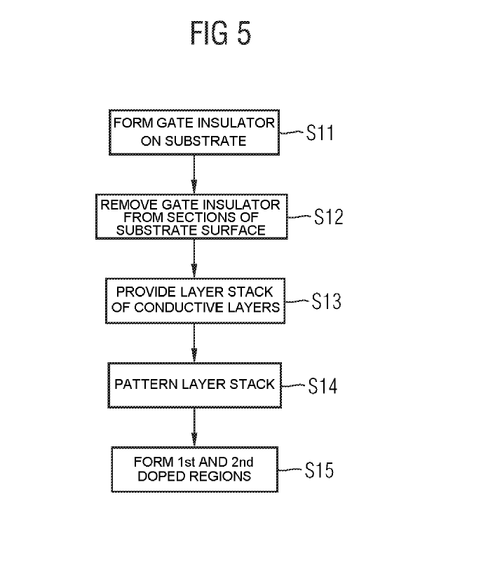

FIG. 5 illustrates a flow diagram of method of manufacturing an integrated circuit comprising a transistor according to an embodiment. A gate insulator is formed on top of a surface of a semiconductor substrate or carrier (S11). Different gate insulators comprising different insulating materials or materials with different thicknesses may be formed in different sections of the substrate surface. For example, a thin gate insulator may be formed in memory array sections comprising floating gate memory cells, and a thicker gate insulator may be formed in periphery sections comprising control or logic transistors.

The gate insulator is removed from sections of the substrate surface (S12), for example, after forming the last gate insulator which may be formed on top of the substrate surface. The gate insulator may be removed using a wet or a dry etching process.

A layer stack comprising a sequence of conductive layers is provided above the substrate surface and the patterned gate insulator (S13). The layer stack may comprise a first conductive layer and a second conductive layer. The layer stack may further comprise an insulating layer, for example between the first and the second conductive layer. The insulating layer may be removed from a portion above contact sections of the substrate surface before providing the conductive layer on top of the insulating layer. Accordingly, an electrically conductive contact results between the first and the second conductive layer above the contact sections of the substrate surface. The layer stack may comprise a doped semiconductor material.

The layer stack is patterned to form a gate electrode and at least one contact structure to the substrate surface in the contact sections (S14). Accordingly, the lowest layer of the layer stack is electrically coupled to the substrate surface within the contact sections.

First and second doped regions are formed within the substrate (S15), wherein at least one doped region is electrically coupled to the contact structure. The doped regions may be formed by implantation of dopants using the contact structure and the gate electrode as an implantation mask. The electrical coupling of the at least one implanted doped region to the contact structure may be provided by a doped region formed by outdiffusion of dopants from the implanted region. The doped regions may have the same conductivity type as the semiconductor material of the layer stack. Furthermore, a doped region may be formed within the substrate adjacent to the contact structure, for example, by outdiffusion of dopants from the semiconductor material of the layer stack during thermal activation of dopants in the first and the second doped region of the transistor.

The described method of manufacturing an integrated circuit may be used for manufacturing a semiconductor memory device comprising memory cells and conductive lines that are configured to address the memory cells. Each memory cell may comprise a transistor, formed at least partially within a semiconductor substrate and comprising a gate electrode comprising a stack of conductive layers. At least one doped region of at least one memory cell or at least one conductive line, which may be formed at least partially within the semiconductor substrate, is coupled to a contact structure or a conductive line, wherein the contact structure or the conductive line comprises a layer stack of conductive layers with the same sequence of conductive layers as the gate electrode. The method of manufacturing such a memory device comprises the method described with respect to FIG. 5, wherein the contact structure may be a contact plug coupled directly to a conductive line or a conductive line.

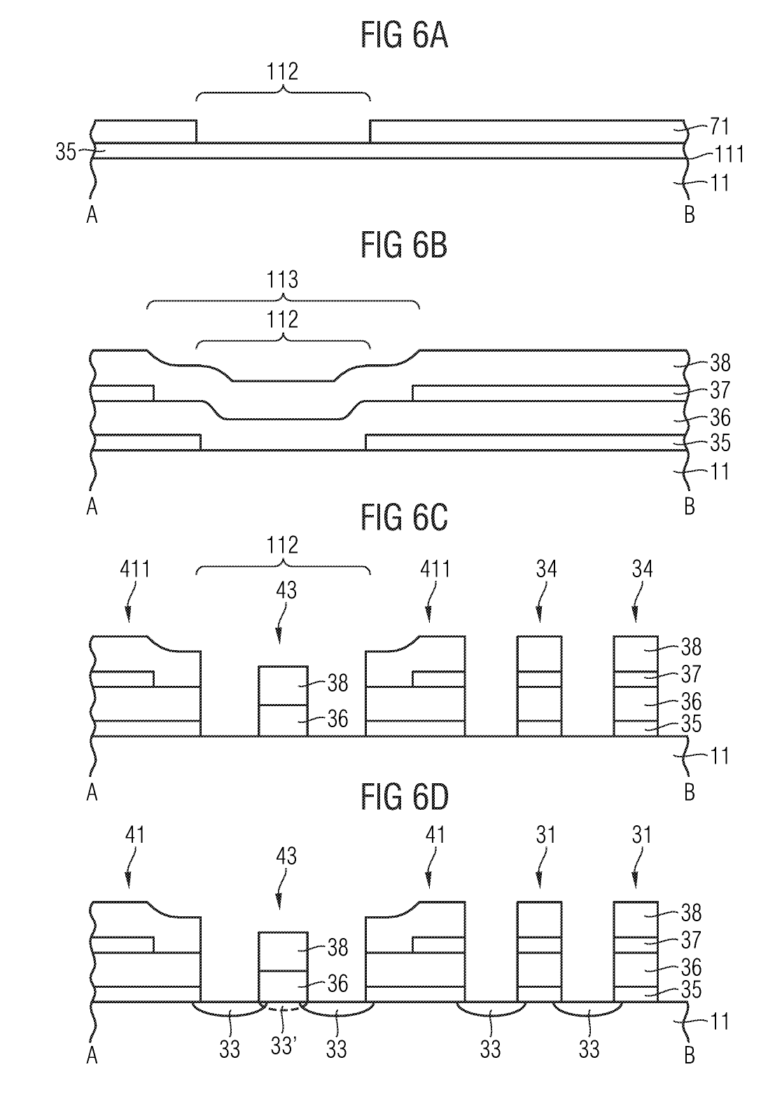

FIGS. 6A to 6D show cross-sectional views of a part of the memory device described with respect to FIG. 3A at different processing steps of the described method of manufacturing a memory device. The section shown in FIGS. 6A to 6D corresponds to the section between lines A and B in FIG. 3A.

According to FIG. 6A, a gate insulator material 35 is disposed on a substrate surface 111 of a semiconductor substrate 11. A resist system comprising, for example, a photo resist, is provided on top of the gate insulator material 35 and patterned. As a result, the gate insulator 35 may be exposed above a contact section 112 of the substrate surface 111.

Referring to FIG. 6B, the section of the exposed gate insulator 35 is removed. As a result, the substrate surface 111 is exposed within the contact section 112. A layer stack comprising a sequence of conductive layers is provided on top of the substrate surface 111 within the contact section 112 and on top of the patterned gate insulator 35. The layer stack may comprise a charge storing layer 36, which is a conductive layer (e.g., polysilicon) and a control gate layer stack 38, which may comprise polysilicon or a metal. The layer stack may further comprise a barrier layer stack 37 disposed between the charge storing layer 36 and the control gate layer stack 38. The barrier layer stack 37 may be formed outside a section 113 of the substrate surface 111. The section 113 may comprise the contact section 112 and may be larger than the section 112. In accordance with further embodiments, the barrier layer stack 37 may be formed in the contact section 112 as well. Only small portions of the charge storing layer 36 may be left uncovered by the barrier layer stack 37 to form a contact between the charge storing layer 36 and the control gate layer stack 38. The absent portions of the barrier layer stack 37 may, for instance, have the shape of a hole.

The structure shown in FIG. 6B may be manufactured by providing the charge storing layer 36 and the barrier layer stack 37 as unpatterned layers, removing the barrier layer stack 37 from the section 113 and providing the control gate layer stack 38 as an unpatterned layer. Removing the barrier layer stack 37 may be accomplished via a lithographic process for patterning a resist layer on top of the barrier layer stack and an etching process using the patterned resist layer as an etching mask. Subsequently and prior to providing the control gate layer stack 38, the resist layer is removed.

The control gate layer stack 38 may be provided as a conformal layer on top of the patterned barrier layer stack 37 and the charge storing layer 36, as shown in FIG. 6B. The conductive layers of the charge storing layer 36 and the control gate layer stack 38 may have the same thicknesses over the whole layer stack. According to another embodiment, the control gate layer stack 38 may be provided as a layer having a planar surface, as illustrated in FIG. 3A. This may be accomplished by a deposition process followed by a planarization process (e.g., CMP (Chemical-mechanical polishing)). As a result, the thickness of the control gate layer stack 38 may be larger within the section 113 than outside the section 113 and may be larger within the section 112 than outside the section 112.

Referring to FIG. 6C, the layer stack is patterned to form gate electrodes 34 of memory cells 31, gate electrodes 411 of first select transistors 41, and a source line 43. This may be accomplished by carrying out a lithographic process for patterning a resist layer on top of the layer stack and an etching process using the patterned resist layer as an etching mask. Accordingly, the source line 43 is formed in the contact section 112. The source line 43 comprises the charge storing layer 36 and the control gate layer stack 38. In accordance with further embodiments, bit line contact structures 44, for example, as shown in FIG. 3A, may be formed by the same process.

Accordingly, since the gate electrodes 34 and 411 and the source line 43 are formed simultaneously by a common (i.e., shared) patterning process, the source line 43 is formed self-aligned with respect to the position of the gate electrodes 34 and 411.

According to FIG. 6D, doped regions 33 are formed within the substrate 11, wherein select gate transistors 41 and storing transistors 31 are formed in a serial connection. The doped regions 33 may be formed by implantation of dopants using the gate structures 411 and 34 and the source line 43 as an implantation mask. The doped regions 33 may extend beneath the gate structures 411 and 34 and beneath the source line 43 due to scattering processes during the implantation process and outdiffusion. Furthermore, outdiffusion may occur during thermal treatment in further processing. Also, an outdiffusion of dopants from the charge storing layer 36 may occur, wherein a doped region 33′ adjacent to the source line 43 may be formed.

Further processing, for example, filling the spaces between the individual memory cells 31, the select gate transistors 41 and the source line 43 with an insulating material and providing conductive lines in higher metallization planes are known to those of ordinary skill in the art and are not further described herein.

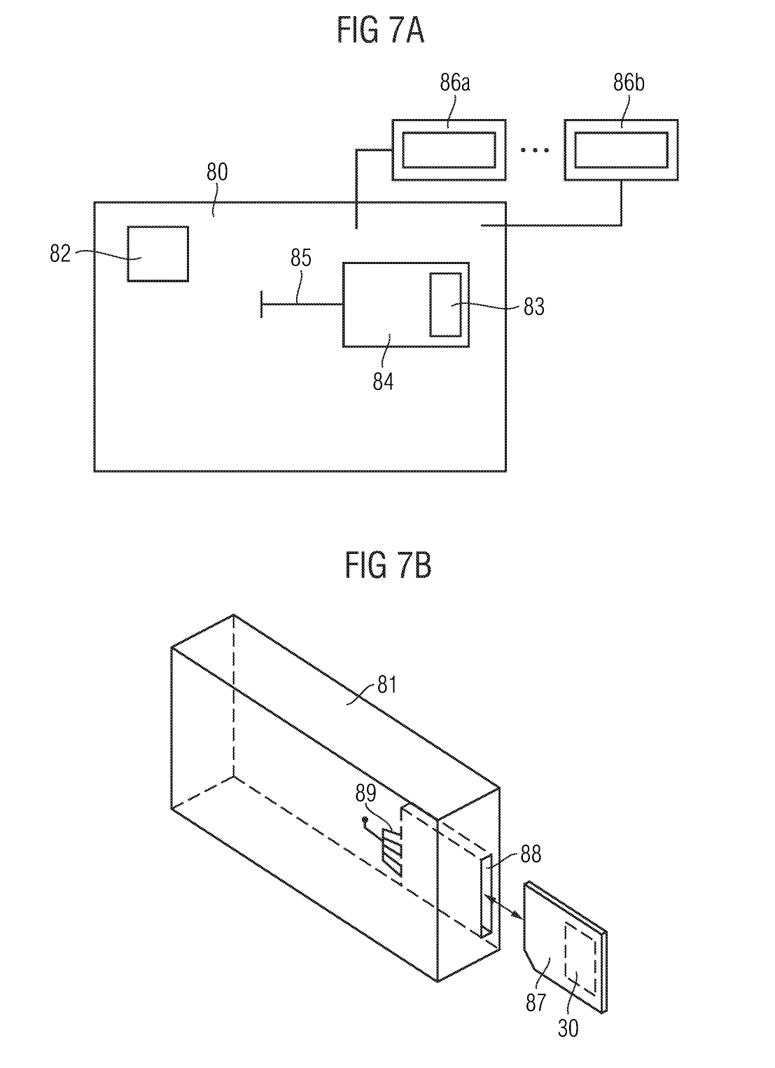

FIG. 7A schematically shows a system 80 according to an embodiment. The system 80 may comprise an interface 85 and a component 84 which is adapted to be interfaced by the interface 85. The system 80, for example the component 84, may comprise an integrated circuit or a memory device 83 as has been explained above. The component 84 may be connected in an arbitrary manner with the interface 85. For example, the component 84 may be externally placed and may be connected with the system 80 by the interface 85. Moreover, the component 84 may be housed inside the system 80 and may be connected with the interface 85. For example, the component 84 may be removably mounted in a slot which is connected with the interface 85. When the component 84 is inserted into the slot, an integrated circuit or a memory device 83 is interfaced by the interface 85. The system 80 may further comprise a processing device 82 for processing data. In addition, the system 80 may further comprise one or more display devices 86a, 86b for displaying data. The system may further comprise components which are configured to implement a specific electronic system. Examples of the electronic system include: a computer (e.g., a personal computer or a notebook), a server, a router, a game console (e.g., a video game console or a portable video game console), a graphics card, a personal digital assistant, a digital camera, a cell phone, an audio system (e.g., any kind of music player) and a video system. The component 84 may be a system for storing data (e.g., an USB stick or a solid state hard disk). The system 80 may be, for example, a portable electronic device.

FIG. 7B shows an exemplary system 81 comprising a memory card 87 including a memory device 30 according to an embodiment. The system 81 comprises a card interface 89, a card slot 88 connected to the card interface 89 and a memory card 87 comprising a memory device 30, which has been explained above. The system 81 may be any kind of electrical device (e.g., a portable electric device or any other kind of electric device). For example, the electric device may be a digital still camera or a video camera, a game apparatus, an electric music instrument, a cell phone, a personal computer, a notebook, a personal digital assistant (PDA) or a PC-card. The system 81 may comprise further components such as processing devices, display devices, further memory devices and others.

The embodiments of the invention described in the foregoing are examples given by way of illustration and the invention is no way limited thereto. Any modification, variation and equivalent arrangement should be considered as being included within the scope of the invention.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit, comprising:
a semiconductor substrate;
first and second doped regions formed within the substrate;
at least one contact structure comprising a first stack including at least two conductive layers, the contact structure being coupled to one of the first and second doped regions; and
a gate electrode comprising a second stack including at least two conductive layers with the same sequence as the conductive layers of the first stack.

2. The integrated circuit of claim 1, further comprising:
a gate insulator insulating the gate electrode from the substrate;
wherein the first stack comprises a layer of a semiconductor material adjacent to the substrate and the second stack comprises a layer of the semiconductor material adjacent to the gate insulator, the semiconductor material having the same conductivity type as the first and second doped regions.

3. The integrated circuit of claim 1, wherein the first and second stacks each further comprise a metal.

4. The integrated circuit of claim 1, further comprising:
a further doped region arranged within the substrate adjacent to the contact structure and coupled to the doped region that is coupled to the contact structure, wherein the further doped region is the same conductivity type as the first and second doped regions.

5. The integrated circuit of claim 1, wherein each conductive layer of the first stack has the same thicknesses as the corresponding conductive layer of the second stack.

6. An integrated circuit, comprising:
a semiconductor substrate;
a contact structure including a first stack with at least two conductive layers; and
first and second transistors, each transistor, including:
first and second doped regions formed within the substrate; and
a gate electrode comprising a second stack of conductive layers with the same sequence as the conductive layers of the first stack;
wherein one of the doped regions of the first transistor and one of the doped regions of the second transistor are coupled to the contact structure.

7. The integrated circuit of claim 6, further comprising:
a gate insulator insulating the gate electrode from the semiconductor substrate;
wherein the first stack comprises a layer of a semiconductor material adjacent to the substrate and the second stack comprises a layer of the semiconductor material adjacent to the gate insulator, the semiconductor material having the same conductivity type as the first and the second doped region.

8. The integrated circuit of claim 6, wherein the first and second stacks each comprise a metal.

9. The integrated circuit of claim 6, further comprising:
a further doped region arranged within the substrate adjacent to the contact structure and coupled to the doped regions of the first and second transistors that are coupled to the contact structure, wherein the further doped region is the same conductivity type as the first and second doped regions of the first and second transistors.

10. The integrated circuit of claim 9, wherein the doped regions of the first and second transistors that are coupled to the contact structure and the further doped region form a continuous doped region within the substrate.

11. The integrated circuit of claim 6, wherein the doped regions, of the first and second transistors that are coupled to the contact structure, form a continuous doped region within the substrate.

12. A memory device, comprising:
a substrate;
a plurality of conductive lines, wherein at least one of the conductive lines or a contact structure adjacent to one of the conductive lines comprises a first stack of at least two conductive layers; and
a plurality of memory cells, each memory cell including: a transistor with first and second doped regions formed within the substrate and a gate electrode comprising a second stack of conductive layers with the same sequence as the conductive layers of the first stack, wherein each memory cell is configured to be addressed by at least one of the conductive lines.

13. The memory device of claim 12, the memory device being a floating gate device, wherein:
the gate electrode comprises a floating gate, a barrier layer stack, and a control gate; and
the at least one conductive line or the contact structure comprises materials the same as and in the same layer sequence as the materials of the floating gate and of the control gate of the gate electrode.

14. The memory device of claim 13, the memory device being a NAND Flash memory device including a plurality of NAND strings, each NAND string comprising:
a source line;
a bit line contact structure;
a plurality of floating gate memory cells coupled to each other in series; and
first and second select transistors arranged at the beginning and the end of each of the series of the memory cells, wherein a doped region of the first select transistor is coupled to the source line and a doped region of the second select transistor is coupled to the bit line contact structure;
wherein at least the source line or the bit line contact structure comprises materials the same as and in the same layer sequence as the materials of the floating gates and of the control gates of the gate electrodes of the memory cells.

15. The memory device of claim 12, wherein the memory device is a charge trapping device.

16. The memory device of claim 12, further comprising:
a conductive buried line formed within the substrate; and
a further doped region arranged within the substrate adjacent to the contact structure or the at least one conductive line and coupled to one of the doped regions of the transistor or to the buried line.

17. The memory device of claim 12, wherein at least one of the conductive lines or the contact structure is self-aligned with respect to the position of the gate electrodes of the memory cells.

18. A method of manufacturing an integrated circuit, the method comprising:
forming a gate insulator on top of a surface of a semiconductor substrate;
removing the gate insulator from sections of the substrate surface;
providing a layer stack comprising at least two conductive layers above the substrate surface and the patterned gate insulator;
patterning the layer stack to form a gate electrode and at least one contact structure on the substrate surface in the sections; and
forming first and second doped regions within the substrate, wherein at least one doped region is electrically coupled to the contact structure.

19. The method of claim 18, wherein the at least one doped region is electrically coupled to the contact structure by a region formed via outdiffusion of dopants from the doped region into the semiconductor substrate.

20. The method of claim 18, wherein a layer of the layer stack comprises a semiconductor material having the same conductivity type as that of the first and second doped regions.

21. The method of claim 20, wherein the at least one doped region is electrically coupled to the contact structure by a region formed via outdiffusion of dopants from the layer stack into the semiconductor substrate.

22. The method of claim 18, wherein the gate electrode and the contact structure are formed simultaneously.

23. The method of claim 18, wherein the conductive layers of the layer stack have the same thicknesses across the extension of the layer stack.

24. A method of manufacturing a memory device, the method comprising:
forming single memory cells, each memory cell including a transistor comprising: a gate electrode, a gate insulator, and first and second doped regions;
forming at least one contact structure adjacent at least one of the doped regions; and
forming conductive lines being configured to address the memory cells;
wherein forming the gate electrodes of the single memory cells and the at least one contact structure include:
forming the gate insulator on a top surface of a semiconductor substrate;
removing the gate insulator from sections of the substrate surface;
providing a layer stack comprising at least two conductive layers in a sequence above the substrate surface and the patterned gate insulator;
patterning the layer stack to form the gate electrodes and at least one contact structure on the substrate surface in the sections; and
forming first and second doped regions within the substrate, wherein at least one doped region is electrically coupled to the contact structure.

25. The method of claim 24, wherein the at least one doped region is electrically coupled to the contact structure by a region formed by outdiffusion of dopants from the at least one doped region into the semiconductor substrate.

26. The method of claim 24, wherein one of the layers of the layer stack comprises a semiconductor material having the same conductivity type as the first and second doped regions.

27. The method of claim 26, wherein the at least one doped region is electrically coupled to the contact structure by a region formed by outdiffusion of dopants from the layer stack into the semiconductor substrate.

28. The method of claim 24, wherein the gate electrodes and the contact structure on the substrate surface are formed simultaneously.

29. A method of manufacturing a memory device, the method comprising:
forming single memory cells, each memory cell including a transistor comprising: a gate electrode, a gate insulator, and first and second doped regions; and
forming conductive lines being configured to address the memory cells;
wherein forming the gate electrodes of the single memory cells and at least one conductive line includes:
forming the gate insulator on a top surface of a semiconductor substrate;
providing a layer stack comprising at least two conductive layers in a sequence above the substrate surface and the gate insulator; and
patterning the layer stack to form the gate electrodes and the at least one conductive line.

30. The method of claim 29, further comprising:
removing the gate insulator from at least one section of the substrate surface before providing the layer stack; and
forming the at least one conductive line in the at least one section, wherein at least one doped region is electrically coupled to the conductive line by a region formed by outdiffusion of dopants from the doped region into the semiconductor substrate.

31. The method of claim 29, wherein a layer of the layer stack comprises a semiconductor material having the same conductivity type as the first and second doped regions.

32. The method of claim 31, further comprising:
removing the gate insulator from at least one section of the substrate surface before providing the layer stack; and
forming the at least one conductive line in the at least one section, wherein at least one doped region is electrically coupled to the conductive line by a region formed by outdiffusion of dopants from the layer stack into the semiconductor substrate.

33. The method of claim 29, wherein the gate electrodes and the at least one conductive line are formed simultaneously.

34. A method of manufacturing a memory device, the method comprising:
forming single memory cells, each cell including: a transistor being at least partially formed in a semiconductor substrate, a gate electrode, and first and second doped regions; and
forming conductive lines configured to address the memory cells;
wherein at least one conductive line or at least one contact structure coupled to a first or second doped region are formed self-aligned with respect to the position of the gate electrodes; and
wherein the gate electrodes and the at least one conductive line or the at least one contact structure are formed simultaneously.

35. The method of claim 34, wherein the at least one contact structure is electrically coupled to the doped region by a region formed by outdiffusion of dopants from the doped region into the semiconductor substrate.

36. The method of claim 34, wherein the at least one conductive line or the at least one contact structure comprises a semiconductor material having the same conductivity type as the first and second doped regions.

37. The method of claim 36, wherein the at least one contact structure is electrically coupled to the doped region by a region formed by outdiffusion of dopants from the semiconductor material of the contact structure into the semiconductor substrate.
